(19) United States
(12) Patent Application Publication
(10) Pub. No.: US 2026/0026099 A1
(43) Pub. Date: Jan. 22, 2026

(54) ROUTING FOR COMPLEMENTARY FIELD-EFFECT TRANSISTORS

(71) Applicant: QUALCOMM Incorporated, San Diego, CA (US)

(72) Inventors: Shreesh NARASIMHA, Charlotte, NC (US); Yan SUN, San Diego, CA (US); Wei-Ta LEE, Hsinchu (TW)

(21) Appl. No.: 18/774,845

(22) Filed: Jul. 16, 2024

(51) Int. Cl. H01L 27/118; H03K 19/20

(52) U.S. Cl. CPC H10D 84/907; H03K 19/20; H10D 84/953; H10D 84/975; H10D 84/981

(57) ABSTRACT

A chip includes a first diffusion region extending in a first direction, and a second diffusion region extending in the first direction, wherein the first diffusion region and the second diffusion region are stacked in a second direction perpendicular to the first direction. The chip also includes a first track extending in the first direction above the first diffusion region and a second track extending in the first direction below the second diffusion region. The chip also includes a first topside contact coupled between a first top surface of the first diffusion region and the first track, a first backside contact coupled between a first bottom surface of the second diffusion region and the second track, and a vertical connector coupled between the first track and the second track.

### BACKGROUND

### Field

Aspects of the present disclosure relate generally to chip layout, and more particularly, to routing for complementary field-effect transistors (CFETs).

### Background

A chip includes many transistors for performing various functions on the chip. The transistors include p-type field-effect transistors (PFETs) and n-type field-effect transistors (NFETs). A PFET may be used in combination with an NFET to provide complementary transistors, which may be used in various circuits on the chip, including, for example, inverters, NAND gates, NOR gates, and other types of circuits.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first diffusion region extending in a first direction, and a second diffusion region extending in the first direction, wherein the first diffusion region and the second diffusion region are stacked in a second direction perpendicular to the first direction. The chip also includes a first rail extending in the first direction, wherein the first rail is above the first diffusion region in the second direction, and the first diffusion region and the first rail are spaced apart in a third direction perpendicular to the first direction and the second direction. The chip also includes a second rail extending in the first direction, wherein the second rail is below the second diffusion region in the second direction, and the second diffusion region and the second rail are spaced apart in the third direction. The chip further includes a first topside contact coupled between a first top surface of the first diffusion region and the first rail, and a first backside contact coupled between a first bottom surface of the second diffusion region and the second rail.

A second aspect relates to a chip. The chip includes a first diffusion region extending in a first direction, and a second diffusion region extending in the first direction, wherein the first diffusion region and the second diffusion region are stacked in a second direction perpendicular to the first direction. The chip includes a first track extending in the first direction, wherein the first track is above the first diffusion region in the second direction, and a second track extending in the first direction, wherein the second track is below the second diffusion region in the second direction. The chip also includes a first topside contact coupled between a first top surface of the first diffusion region and the first track, a first backside contact coupled between a first bottom surface of the second diffusion region and the second track, a vertical connector extending in the second direction between the first track and the second track, a first via disposed between the vertical connector and the first track, and a second via disposed between the vertical connector and the second track.

A third aspect relates to a chip. The chip includes a first diffusion region extending in a first direction, and a second diffusion region extending in the first direction, wherein the first diffusion region and the second diffusion region are stacked in a second direction perpendicular to the first direction. The chip also includes a track extending in the first direction, wherein the track is above the first diffusion region in the second direction. The chip also includes a first topside contact coupled between a first top surface of the first diffusion region and the track, a vertical connector extending in the second direction, a first via disposed between the vertical connector and the track, and a backside contact coupled between a bottom surface of the second diffusion region and the vertical connector.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a FinFET according to certain aspects of the present disclosure.

FIG. 1C shows a perspective view of the transistor implemented with a gate-all-around FET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2 shows a top view of an exemplary layout of diffusion regions and gates for providing complementary transistors according to certain aspects of the present disclosure.

FIG. 3 shows an example of contacts disposed on the diffusion regions of FIG. 2 according to certain aspects of the present disclosure.

FIG. 4A shows another example of contacts disposed on the diffusion regions of FIG. 2 according to certain aspects of the present disclosure.

FIG. 4B shows an example of signal routing in a first metal layer coupled to two of the contacts of FIG. 4A according to certain aspects of the present disclosure.

FIG. 4C shows an example of signal routing in a second metal layer coupled to the signal routing in the first metal layer of FIG. 4B according to certain aspects of the present disclosure.

FIG. 5A shows yet another example of contacts disposed on the diffusion regions of FIG. 2 according to certain aspects of the present disclosure.

FIG. 5B shows an example of signal routing in a first metal layer coupled to two of the contacts of FIG. 5A according to certain aspects of the present disclosure.

FIG. 5C shows an example of signal routing in a second metal layer coupled to the signal routing in the first metal layer of FIG. 5B according to certain aspects of the present disclosure.

FIG. 5D shows another example of signal routing in the first metal layer coupled to two of the contacts of FIG. 5A according to certain aspects of the present disclosure.

FIG. 5E shows an example of signal routing in the second metal layer coupled to the signal routing in the first metal layer of FIG. 5D according to certain aspects of the present disclosure.

FIG. 6A shows a perspective view of an exemplary complementary field-effect transistor (CFET) structure according to certain aspects of the present disclosure.

FIG. 6B shows a perspective view of the CFET structure of FIG. 6A in which gates of the CFET structure are shown in phantom according to certain aspects of the present disclosure.

FIG. 7 shows a perspective view of an exemplary routing structure for providing power and signal routing for the CFET structure according to certain aspects of the present disclosure.

FIG. 8A shows a top view of an example of power routing and signal routing using the routing structure according to certain aspects of the present disclosure.

FIG. 8B shows a bottom view of an example of power routing and signal routing using the routing structure according to certain aspects of the present disclosure.

FIG. 8C shows a top view of an example of cells sharing a supply rail according to certain aspects of the present disclosure.

FIG. 9A shows a cross-sectional view taken along a first cross-section line in FIG. 8A according to certain aspects of the present disclosure.

FIG. 9B shows a cross-sectional view taken along a second cross-section line in FIG. 8A according to certain aspects of the present disclosure.

FIG. 9C shows a cross-sectional view taken along a third cross-section line in FIG. 8A according to certain aspects of the present disclosure.

FIG. 9D shows the cross-sectional view of FIG. 9C further including a via disposed between a vertical connector and a backside track according to certain aspects of the present disclosure.

FIG. 10 shows a circuit schematic of an exemplary NAND gate that may be implemented with the CFET structure using the routing structure according to certain aspects of the present disclosure.

FIG. 11A shows a top view of another example of power routing and signal routing using the routing structure according to certain aspects of the present disclosure.

FIG. 11B shows a bottom view of another example of power routing and signal routing using the routing structure according to certain aspects of the present disclosure.

FIG. 12A shows a cross-sectional view taken along a first cross-section line in FIG. 11A according to certain aspects of the present disclosure.

FIG. 12B shows a cross-sectional view taken along a second cross-section line in FIG. 11A according to certain aspects of the present disclosure.

FIG. 12C shows a cross-sectional view taken along a third cross-section line in FIG. 11A according to certain aspects of the present disclosure.

FIG. 13A shows a perspective view of an exemplary routing structure according to certain aspects of the present disclosure.

FIG. 13B shows a side view of the exemplary routing structure of FIG. 13A according to certain aspects of the present disclosure.

FIG. 14 shows an example of a cell including the exemplary routing structure of FIG. 13A according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

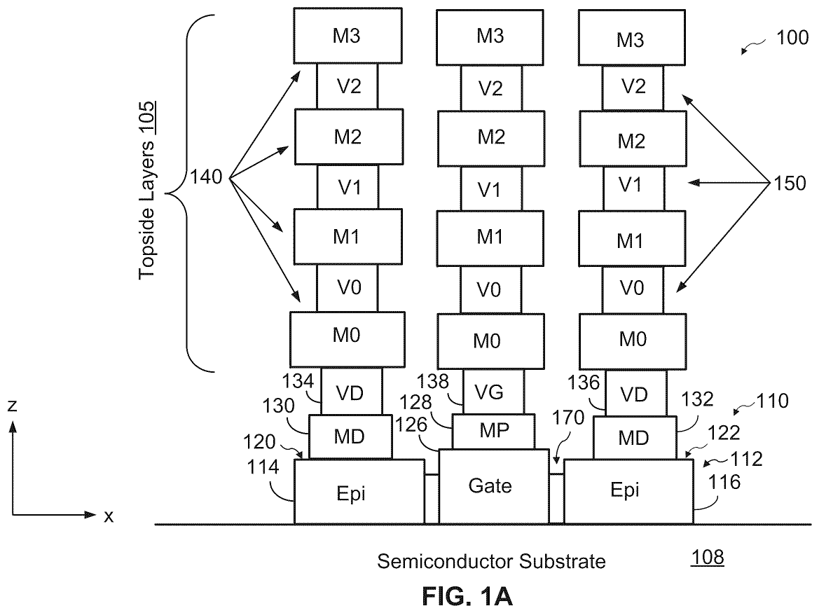

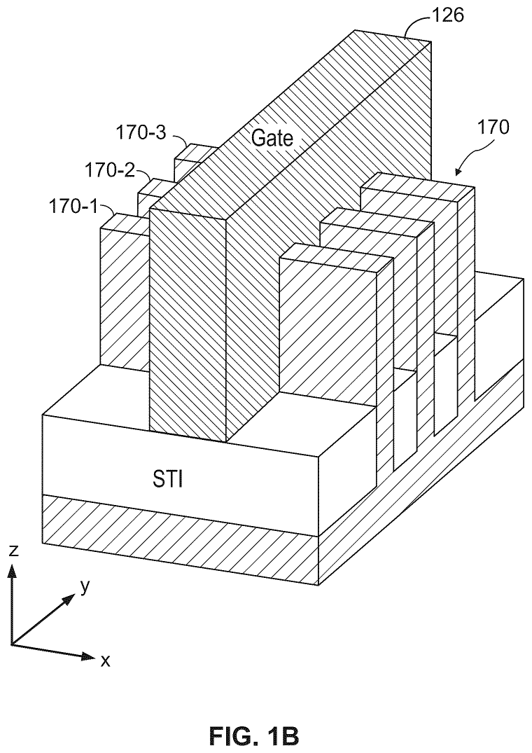

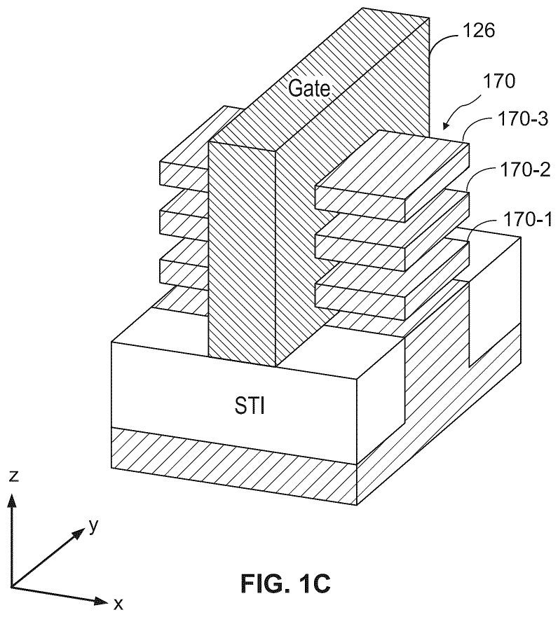

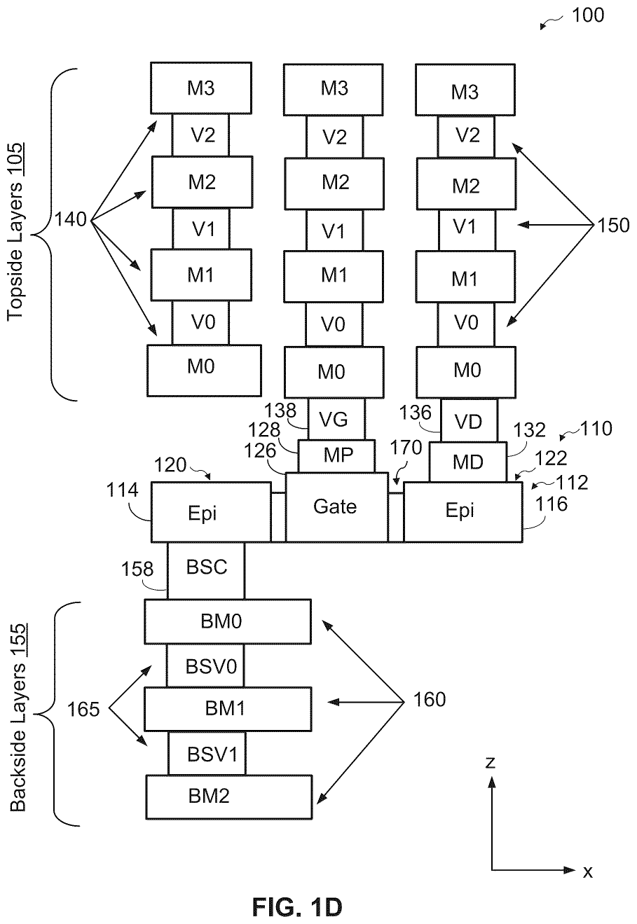

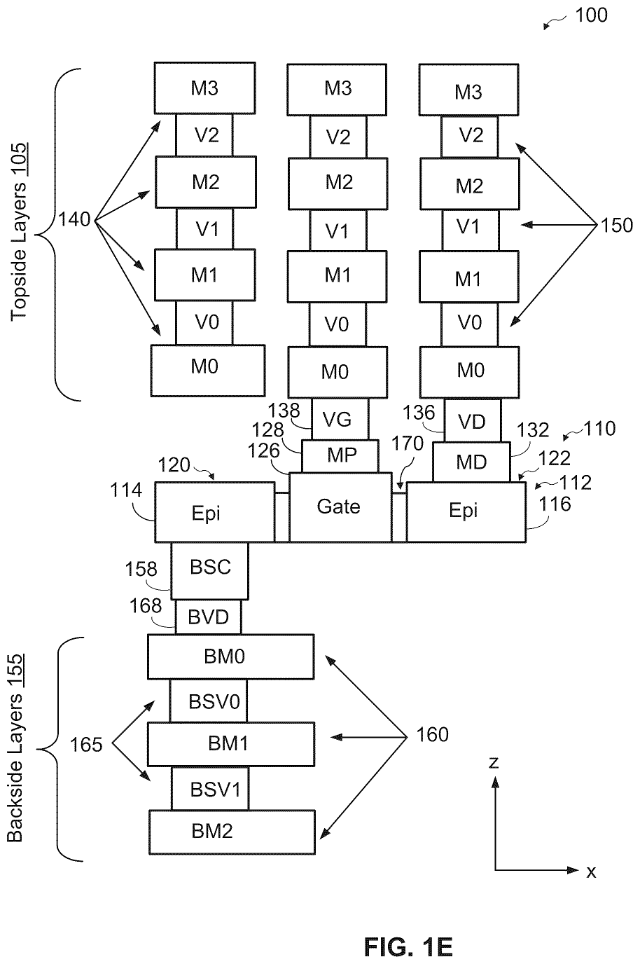

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor. For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epi layers may be coupled to opposite sides of the one or more channels 170, as discussed further below.

For the example of a FinFET process, the gate 126 may surround each of the one or more channels 170 on three sides. In this regard, FIG. 1B shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins. In certain aspects, the chip 100 may include shallow trench isolation (STI) to reduce leakage between devices on the chip 100. In some implementations, the STI may be omitted.

For the example of a gate-all-around FET process, the gate 126 may surround each of the one or more channels 170 (also referred as ribbons) on four sides. In this regard, FIG. 1C shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a first spacer (not shown in FIG. 1A) between the gate 126 and the first epi layer 114 and a second spacer (not shown in FIG. 1A) between the gate 126 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including supply rails for distributing power to the transistor 110 and other transistors integrated on the chip 100. A supply rail may also be referred to as a power rail or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for case of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V3. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 138 disposed between the gate contact 128 and metal layer M0, in which the via 138 couples the gate contact 128 (and hence the gate 126) to metal layer M0. For implementations where the gate contact 128 is omitted, the via 138 may be disposed between the gate 126 and metal layer M0 without an intervening gate contact. In this example, the chip 100 also includes a via 134 disposed between the first contact 130 and metal layer M0, in which the via 134 couples the first contact 130 to metal layer M0. The chip 100 also includes a via 136 disposed between the second contact 132 and metal layer M0, in which the via 136 couples the second contact 132 to metal layer M0.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for case of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing. In general, the present disclosure is not limited to a particular allocation of power routing and signal routing between the topside layers 105 and the backside layers 155.

Although one gate 126 is shown in FIGS. 1A to 1E, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to implement a circuit (e.g., an inverter, a driver, a logic gate, combinational logic, a latch, a flip-flop, a bit cell, or another type of circuit). The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell. A cell that is defined in a standard cell library may also be referred to as a standard cell.

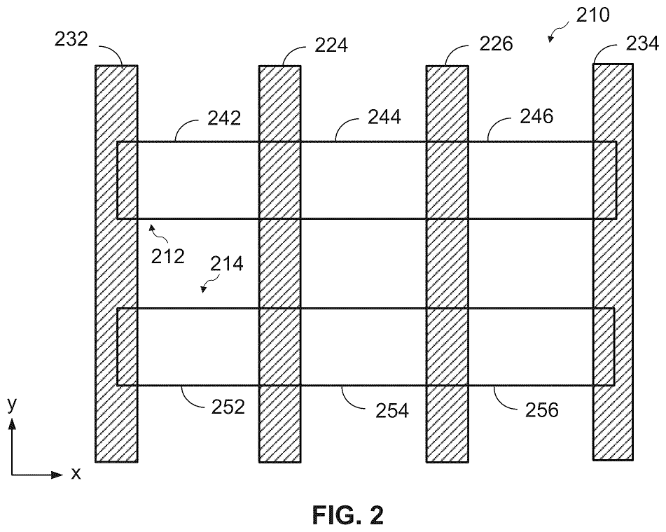

FIG. 2 shows a top view of an exemplary layout 210 providing complementary transistors according to certain aspects of the present disclosure. The layout 210 may be used to implement a circuit that includes complementary transistors such as an inverter, a NAND gate, a NOR gate, or another type of circuit. The layout 210 may be located within a standard cell.

In this example, the layout 210 includes a first diffusion region 212 and a second diffusion region 214 extending in the x direction, in which the first diffusion region 212 and the second diffusion region 214 are placed (i.e., laid) side by side in the y direction. The first diffusion region 212 may be a p-type diffusion region and the second diffusion region 214 may be an n-type diffusion region to provide complementary transistors. Each of the diffusion regions 212 and 214 may include one or more channels extending in the x direction (e.g., one or more instances of the one or more channels 170).

The layout 210 also includes gates 224 and 226 extending in the y direction and spaced apart from one another in the x direction. Each of the gates 224 and 226 may include a gate metal (e.g., a high-k metal gate (HKMG)), polysilicon, and/or another gate material. The layout 210 may include additional gates 232 and 234 spaced apart from the gates 224 and 226 in the x direction (e.g., at a uniform pitch). The additional gates 224 and 226 may be dummy gates (also known as non-functional gates). In other implementations, the gates 224 and 226 may be used to implement additional transistors. In other implementations, the additional gates 232 and 234 may be replaced with diffusion breaks (e.g., single diffusion breaks or double diffusion breaks).

In this example, the first diffusion region 212 is a p-type diffusion region to provide one or more PFETs and the second diffusion region 214 is an n-type diffusion region to provide one or more NFETs. Thus, the diffusion regions 212 and 214 (which are placed side by side) provide complementary transistors. In the example shown in FIG. 2, the first diffusion region 212 includes a first source/drain 242 to the left of the gate 224, a second source/drain 244 between the gates 224 and 226, and a third source/drain 246 to the right of the gate 226. The second diffusion region 214 includes a fourth source/drain 252 to the left of the gate 224, a fifth source/drain 254 between the gates 224 and 226, and a sixth source/drain 256 to the right of the gate 226. Each source/drain may include an epi layer (e.g., an instance of epi layer 114 or 116).

In this example, the layout 210 may be used to implement various circuits that include complementary transistors. Examples of such circuits include inverters, NAND gates, NOR gates, and other types of circuits.

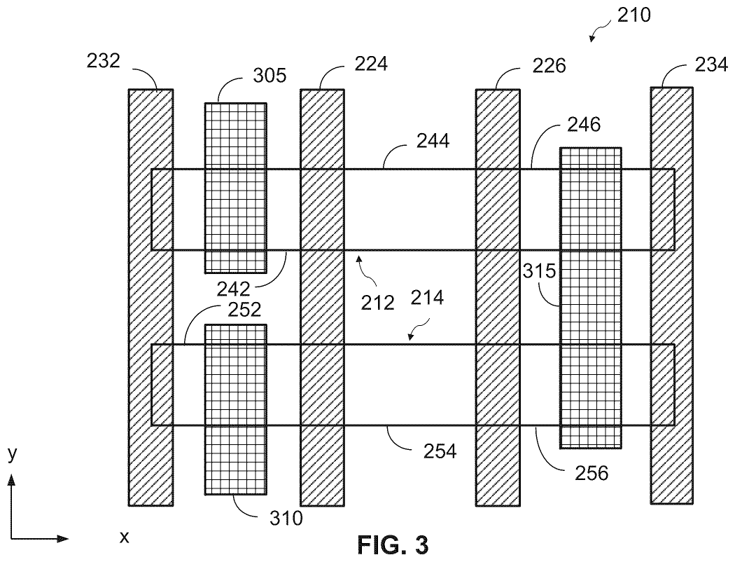

In this regard, FIG. 3 shows an example in which the layout 210 is used to implement an inverter. In this example, the layout 210 includes a first contact 305 disposed on the first source/drain 242, and a second contact 310 disposed on the fourth source/drain 252. The first contact 305 is used to couple to the first source/drain 242 to a supply rail (not shown), and the second contact 310 is used to couple the fourth source/drain 252 to a ground rail (not shown).

In this example, the layout includes a third contact 315 (e.g., in contact layer MD in FIG. 1A) disposed on the third source/drain 246 and the sixth source/drain 256. The third contact 315 is used to couple the third source/drain 246 and the sixth source/drain 256 to the output of the inverter. In this example, the third contact 315 extends in the y direction to make contact with both the third source/drain 246 and the sixth source/drain 256. Thus, in this example, the third source/drain 246 and the sixth source/drain 256 are coupled to the output through a shared contact.

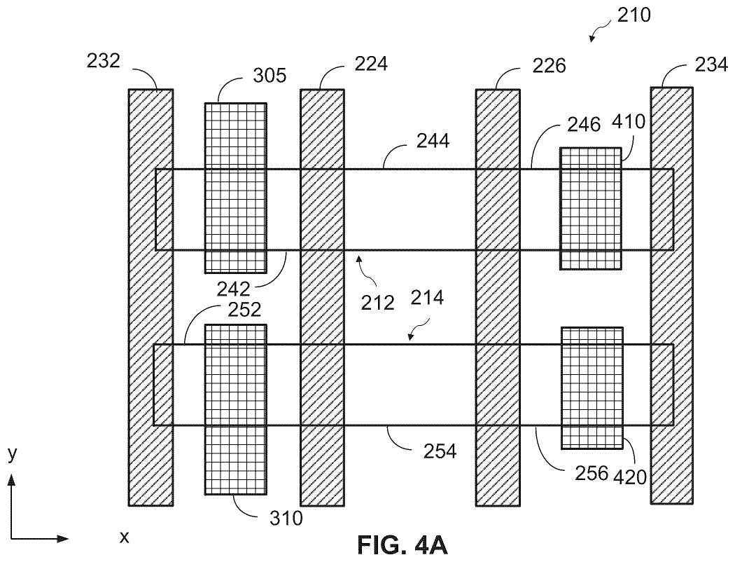

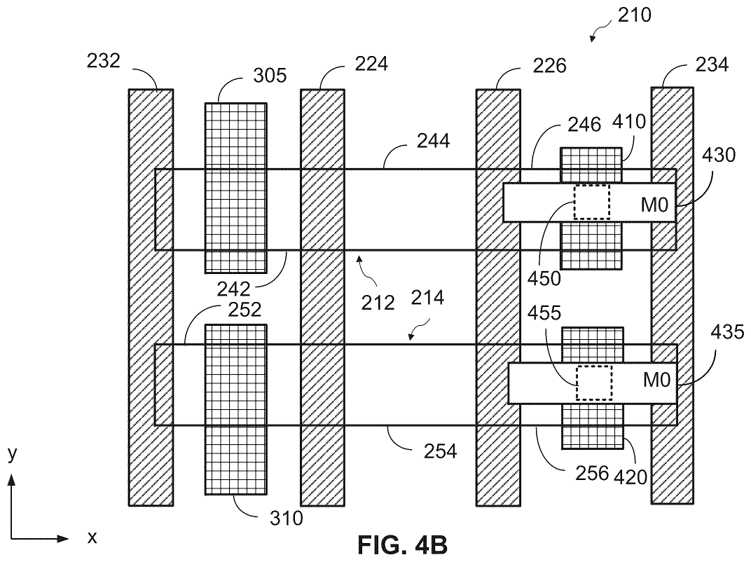

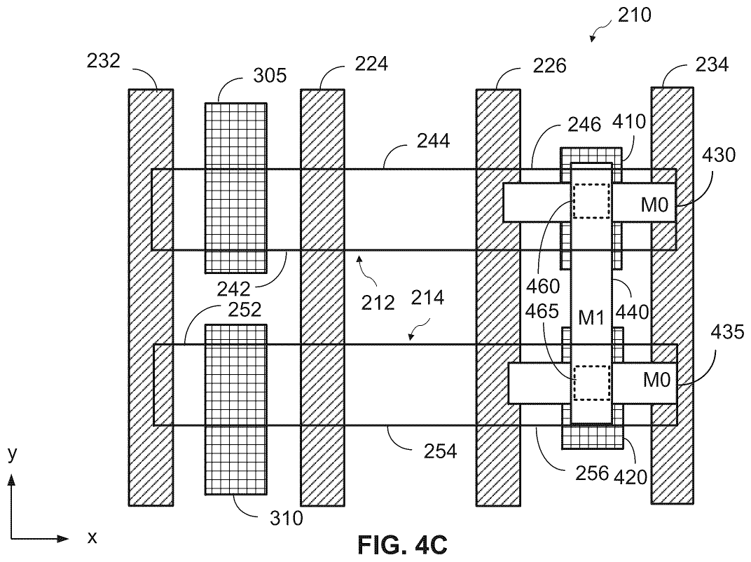

FIG. 4A shows another example in which the layout 210 is used to implement an inverter. In this example, the layout 210 includes the first contact 305 and the second contact 310 discussed above with reference to FIG. 3.

In this example, the layout 210 includes separate contacts for the third source/drain 246 and the sixth source/drain 256 instead of the shared contact (i.e., the third contact 315 shown in FIG. 3). The separate contacts includes a third contact 410 disposed on the third source/drain 246 and a fourth contact 420 disposed on the sixth source/drain 256. In this example, the contacts 410 and 420 are aligned in the x direction, as shown in FIG. 4A. The contacts 410 and 420 may be in contact layer MD shown in FIG. 1A.

FIG. 4B shows an example in which the chip 100 includes a first signal path 430 extending in the x direction over the third contact 410, and a second signal path 435 extending in the x direction over the fourth contact 420. The first and second signal paths 430 and 435 are in metal layer M0. The first signal path 430 is coupled to the third contact 410 by a first via 450 (e.g., VD via in FIG. 1A) disposed between the third contact 410 and the first signal path 430, and the second signal path 435 is coupled to the fourth contact 420 by a second via 455 (e.g., VD via in FIG. 1A) disposed between the fourth contact 420 and the second signal path 435. In FIG. 4B, the vias 450 and 455 are shown in dotted line to indicate that the vias 450 and 455 are below metal layer M0.

FIG. 4C shows an example in which the chip 100 further includes a third signal path 440 extending in the y direction over the first signal path 430 and the second signal path 435. The third signal path 440 is in metal layer M1, which is above metal layer M0. In this example, the third signal path 440 is coupled to the first signal path 430 by a third via 460 (e.g., V0 via in FIG. 1A) and coupled to the second signal path 435 by a fourth via 465 (e.g., V0 via in FIG. 1A). In FIG. 4C, the vias 460 and 465 are shown in dotted line to indicate that the vias 460 and 465 are below metal layer M1. In this example, the contacts 410 and 420 are coupled to the output through the signal path in metal layer M1 (i.e., the third signal path 440), which is aligned with the contacts 410 and 420 in the x direction, as shown in FIG. 4B.

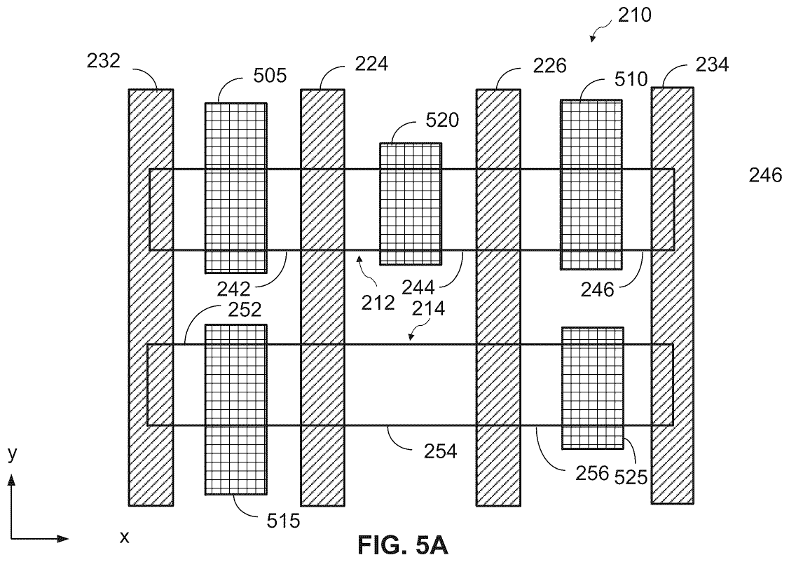

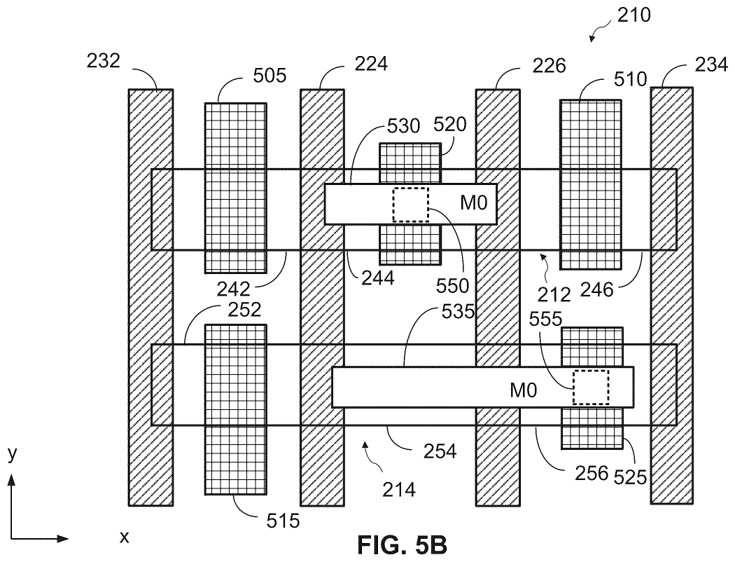

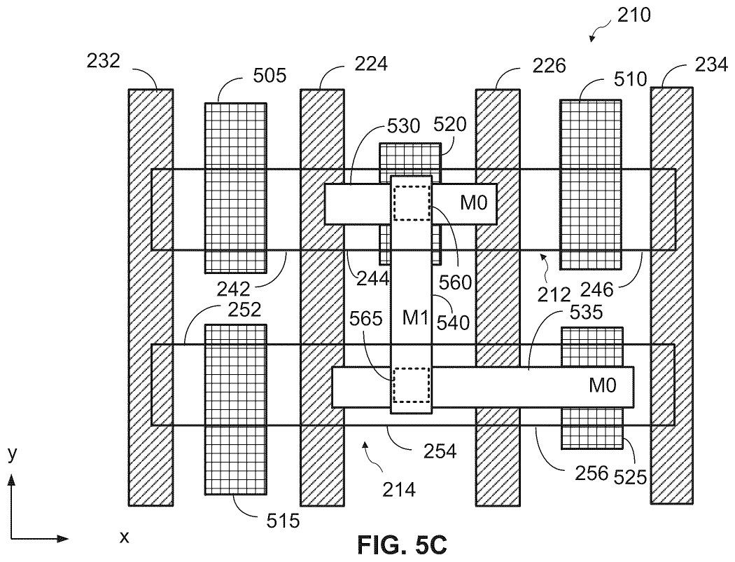

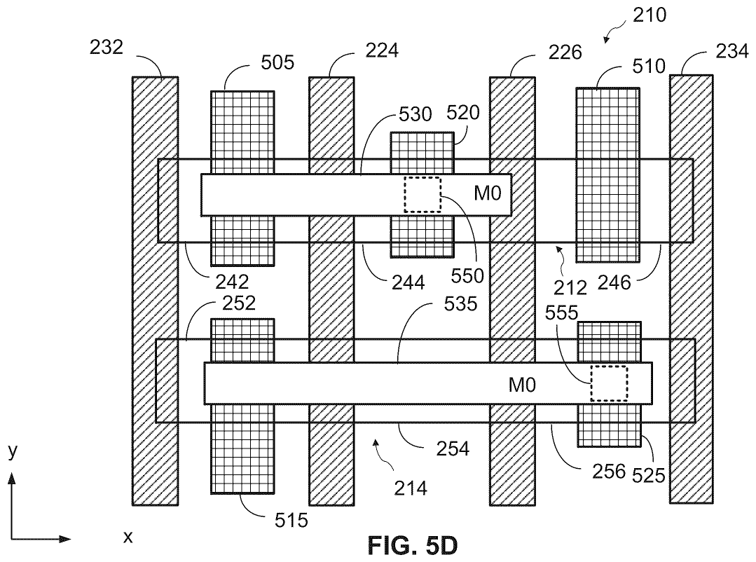

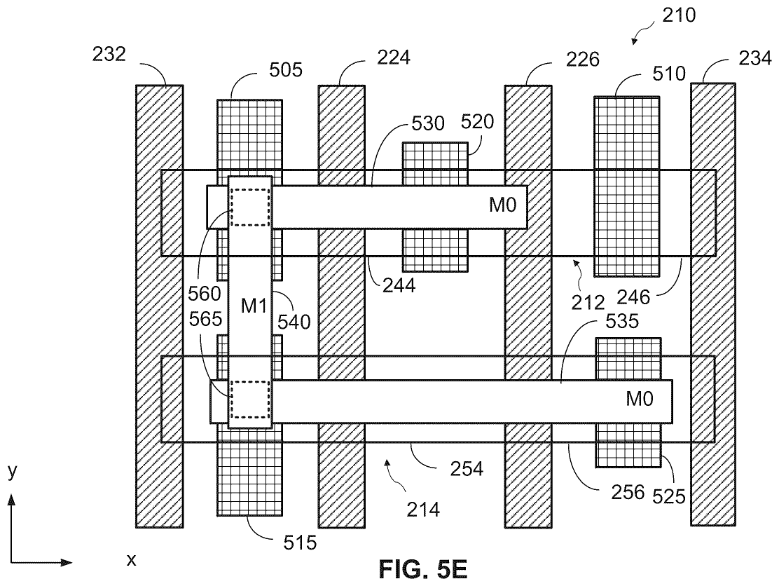

FIG. 5A shows an example in which the layout 210 is used to implement a NAND gate according to certain aspects. In this example, the layout 210 includes a first contact 505 disposed on the first source/drain 242, a second contact 510 disposed on the third source/drain 246, and a third contact 515 disposed on the fourth source/drain 252. The first contact 505 and the second contact 510 are used to couple to the first source/drain 242 and the third source/drain 246, respectively, to the supply rail (not shown). The third contact 515 is used to couple the fourth source/drain 252 to the ground rail (not shown).

In this example, the layout 210 also includes a fourth contact 520 disposed on the second source/drain 244 and a fifth contact 525 disposed on the sixth source/drain 256. The fourth contact 520 and the fifth contact 525 are used to couple the second source/drain 244 and the sixth source/drain 256 to the output of the NAND gate. In this example, the contacts 520 and 525 for the output are not aligned in the x direction. In other words, the fifth contact 525 is offset from the fourth contact 520 in the x direction. In contrast, the contacts 410 and 420 in the example in FIG. 4A are aligned in the x direction.

FIG. 5B shows an example in which the chip 100 includes a first signal path 530 and extending in the x direction over the fourth contact 520, and a second signal path 535 extending in the x direction over the fifth contact 525. The first and second signal paths 530 and 535 are in metal layer M0. The first signal path 530 is coupled to the fourth contact 520 by a first via 550 (e.g., VD via in FIG. 1A) disposed between the fourth contact 520 and the first signal path 530, and the second signal path 535 is coupled to the fifth contact 525 by a second via 555 (e.g., VD via in FIG. 1A) disposed between the fifth contact 525 and the second signal path 535. In FIG. 5B, the vias 550 and 555 are shown in dotted line to indicate that the vias 550 and 555 are below metal layer M0.

FIG. 5C shows an example in which the chip 100 further includes a third signal path 540 extending in the y direction over the first signal path 530 and the second signal path 535. The third signal path 540 is in metal layer M1, which is above metal layer M0. In this example, the third signal path 540 is coupled to the first signal path 530 by a third via 560 e.g., V0 via in FIG. 1A) and coupled to the second signal path 535 by a fourth via 565 (e.g., respective V0 vias in FIG. 1A). In FIG. 5C, the vias 560 and 565 are shown in dotted line to indicate that the vias 560 and 565 are below metal layer M1. In this example, the contacts 520 and 525 are coupled to the output through the signal path in metal layer M1 (i.e., the third signal path 540). In this example, the signal path in metal layer M1 is aligned with the fourth contact 520 in the x direction but is offset from the fifth contact 525 in the x direction. In this example, the output coupling in metal layer M1 may be referred to as M1 single offset since the signal path in metal layer M1 (i.e., the third signal path 540) is offset from one of the two contacts 520 and 525 in the x direction.

FIG. 5D shows another example in which the first signal path 530 and the second signal path 535 extend farther to the left in the x direction compared with FIG. 5B. FIG. 5E shows an example in which the third signal path 540 in metal layer M1 is offset from both contacts 520 and 525. In this example, the output coupling in metal layer M1 may be referred to as M1 double offset since the signal path in metal layer M1 (i.e., the third signal path 540) is offset from both contacts 520 and 525 in the x direction.

As discussed above, complementary transistors in the exemplary layout 210 include a PFET and an NFET that are arranged side by side in the y direction.

In certain aspects, complementary transistors may include a PFET and an NFET that are stacked vertically in the z direction. Stacking the PFET and the NFET vertically reduces cell height in the y direction compared with the side-by-side arrangement of the PFET and the NFET illustrated in FIG. 2. The reduced cell height allows a larger number of cells to be placed on the chip 100.

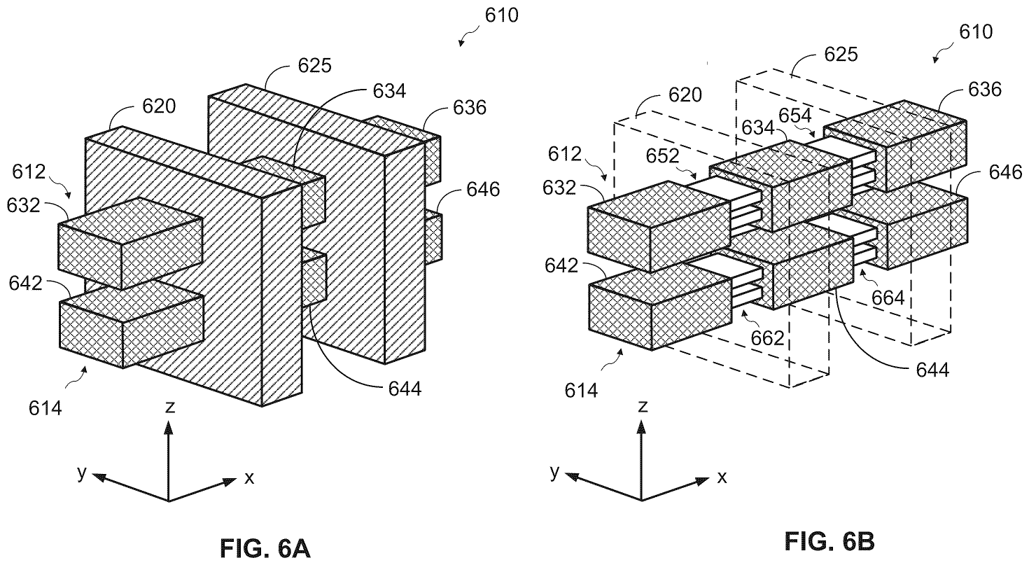

In this regard, FIG. 6A shows a perspective view of a complementary field-effect transistor (CFET) structure 610 with a stacked P-N architecture according to certain aspects. As discussed further below, the CFET structure 610 provides stacked complementary transistors. The CFET structure 610 may be used to implement a circuit that includes complementary transistors such as an inverter, a NAND gate, a NOR gate, or another type of circuit.

The CFET structure 610 includes a first diffusion region 612 extending in the x direction and a second diffusion region 614 extending in the x direction. The first diffusion region 612 and the second diffusion region 214 are stacked vertically in the z direction, in which the first diffusion region 612 and the second diffusion region 614 are spaced apart in the z direction. In the example in FIG. 6A, the first diffusion region 612 and the second diffusion region 614 are aligned in the y direction. The first diffusion region 612 may be a p-type diffusion region and the second diffusion region 614 may be an n-type diffusion region to provide complementary transistors. However, it is to be appreciated that the present disclosure is not limited to this example. In other implementations, the first diffusion region 612 may be an n-type diffusion region and the second diffusion region 614 may be a p-type diffusion region.

The CFET structure 610 also includes a first gate 620 and a second gate 625, in which each of the gates 620 and 625 extends in the y direction and the z direction. The gates 620 and 625 are spaced apart from one another in the x direction. Each of the gates 620 and 625 may include a gate metal (e.g., a high-k metal gate (HKMG)), polysilicon, and/or another gate material. It is to be appreciated that the positions of the diffusion regions 612 and 614 with respect to the gates 620 and 625 in the y direction and the z direction are not limited to the example shown in FIG. 6A.

In the example in FIG. 6A, the first diffusion region 612 includes a first source/drain 632 to the left of the first gate 620 in the x direction, a second source/drain 634 between the gates 620 and 625, and a third source/drain 636 to the right of the second gate 625 in the x direction. Each of the first source/drain 632, the second source/drain 634, and the third source/drain 636 may include a respective epitaxial (epi) layer. An epi layer may include epitaxially grown or deposited silicon, a silicon-based material (e.g., silicon-germanium), or any combination thereof. It is to be appreciated that the first source/drain 632, the second source/drain 634, and the third source/drain 636 may have shapes that differ from the exemplary shapes shown in FIG. 6A.

In this example, the first diffusion region 612 may include one or more channels 652 passing through the first gate 620 and one or more channels 654 passing through the second gate 625, as shown in FIG. 6B (which shows the gates 620 and 625 in phantom). In the example shown in FIG. 6B, the one or more channels 652 are coupled between the first source/drain 632 and the second source/drain 634, and the one or more channels 654 are coupled between the second source/drain 634 and the third source/drain 636. The one or more channels 652 and the one or more channels 654 may include nanosheets, nanowires, fins, or other types of channels.

In the example in FIG. 6A, the second diffusion region 614 includes a fourth source/drain 642 to the left of the first gate 620 in the x direction, a fifth source/drain 644 between the gates 620 and 625, and a sixth source/drain 646 to the right of the second gate 625 in the x direction. Each of the fourth source/drain 642, the fifth source/drain 644, and the sixth source/drain 646 may include a respective epi layer. It is to be appreciated that the fourth source/drain 642, the fifth source/drain 644, and the sixth source/drain 646 may have shapes that differ from the exemplary shapes shown in FIG. 6A.

In this example, the second diffusion region 614 may include one or more channels 662 passing through the first gate 620 and one or more channels 664 passing through the second gate 625, as shown in FIG. 6B (which shows the gates 620 and 625 in phantom). In the example shown in FIG. 6B, the one or more channels 662 are coupled between the fourth source/drain 642 and the fifth source/drain 644, and the one or more channels 664 are coupled between the fifth source/drain 644 and the sixth source/drain 646. The one or more channels 662 and the one or more channels 664 may include nanosheets, nanowires, fins, or other types of channels.

In this example, the vertically stacked diffusion regions 612 and 614 provide the CFET structure 610 with at least one pair of PFET and NFET that are vertically stacked. When the CFET structure 610 is included in a cell, the vertically stacked PFET and NFET reduce the height of the cell in the y direction compared with the side-by-side P-N arrangement illustrated in FIG. 2.

However, area efficient power routing and signal routing for the CFET structure 610 is challenging, which may prevent the maximum cell height reduction potential of the CFET structure 610 from being realized. For example, a large challenge with signal routing for the CFET structure 610 is providing P-N coupling (i.e., coupling between a source/drain of a PFET and a source/drain of an NFET). Accordingly, techniques for providing more area efficient routing for the CFET structure 610 are desirable.

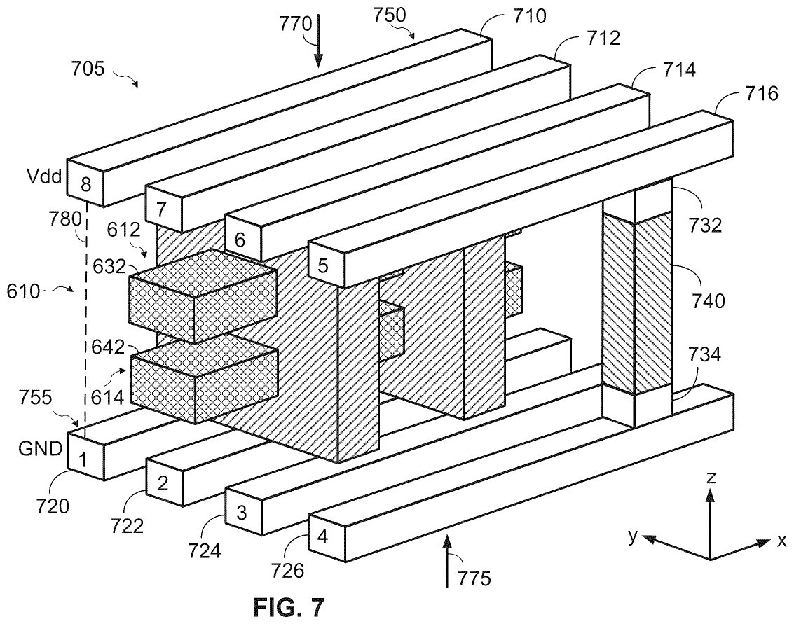

FIG. 7 shows a perspective view of a routing structure 705 for providing efficient power routing and signal routing for the CFET structure 610 according to certain aspects. The routing structure 705 includes a set of topside tracks 710, 712, 714, and 716 above the CFET structure 610. Each of the topside tracks 710, 712, 714, and 716 extends in the x direction. The topside tracks 710, 712, 714, and 716 are spaced apart from one another in the y direction. In certain aspects, the topside tracks 710, 712, 714, and 716 are in metal layer M0.

The routing structure 705 also includes a set of backside tracks 720, 722, 724, and 726 below (i.e., under) the CFET structure 610. Each of the backside tracks 720, 722, 724, and 726 extends in the x direction. The backside tracks 720, 722, 724, and 726 are spaced apart from one another in the y direction. In certain aspects, the backside tracks 720, 722, 724, and 726 are in backside metal layer BM0.

In the example in FIG. 7, each of the topside tracks 710, 712, 714, and 716 and each of the backside tracks 720, 722, 724, and 726 is elongated and extends in the lengthwise direction.

In this example, the topside track 710 and the backside track 720 are used as rails for routing power to the CFET structure 610. For example, the topside track 710 (labeled 8) may be used as a supply rail 750 for providing a supply voltage Vdd, and the backside track 720 (labeled 1) may be used as a ground rail 755, or vice versa. In the example in FIG. 7, the supply rail 750 and the ground rail 755 are aligned in the y direction. In other words, the supply rail 750 and the ground rail 755 are in-line vertically in this example. For the example where the CFET structure 610 is located in a standard cell, the supply rail 750 and the ground rail 755 may be located on an edge 780 of the cell (indicated by the dashed vertical line in FIG. 7). As discussed further below, this feature allows the supply rail 750 and the ground rail 755 to be shared with another cell in an adjacent row for improved area efficiency.

As discussed further below, the first diffusion region 612 may be coupled to the supply rail 750 through one or more topside contacts (e.g., contact layer MD in FIGS. 1A, 1D, and 1E) and one or more vias (e.g., via VD in FIGS. 1A, 1D, and 1E). The second diffusion region 614 may be coupled to the ground rail 755 through one or more backside contacts (e.g., backside contact layer BSC in FIGS. 1D and 1E) and one or more vias (e.g., via BVD in FIG. 1E).

In the example in FIG. 7, the routing structure 705 also includes a vertical connector 740 extending in the z direction. The vertical connector 740 may be coupled between the topside track 716 (labeled 5) and the backside track 726 (labeled 4). As discussed further below, the vertical connector 740 facilitates P-N coupling for the CFET structure 610. In the example shown in FIG. 7, the routing structure 705 includes a first via 732 disposed between a top surface of the vertical connector 740 and the topside track 716, and a second via 734 disposed between a bottom surface of the vertical connector 740 and the backside track 726. Thus, in this example, the vertical connector 740 is coupled to the topside track 716 through the first vias 732 and coupled to the backside track 726 through the second via 734. As discussed further below, the vias 732 and 734 provide coupling flexibility for the vertical connector 740. It is to be appreciated that the vertical connector 740 is not limited to the exemplary location shown in FIG. 7, and that the vertical connector 740 may be placed at other locations between the topside track 716 and the backside track 726 in the x direction.

In this example, the topside track 712 (labeled 7) and the topside track 714 (labeled 6) are available for signal routing, and the backside track 722 (labeled 2) and the backside track 724 (labeled 3) are available for signal routing. For example, the topside tracks 712 and 714 may be used for input signal routing and the backside tracks 722 and 724 may be used for signal routing within a cell. However, it is to be appreciated that the tracks 712, 714, 722, and 724 are not limited to this example.

Exemplary features of the routing structure 705 will now be discussed using an example in which the CFET structure 610 implements a NAND gate. However, it is to be appreciated that the routing structure 705 and the CFET structure 610 are not limited to a NAND gate, and that the CFET structure 610 may be used to implement other types of circuits.

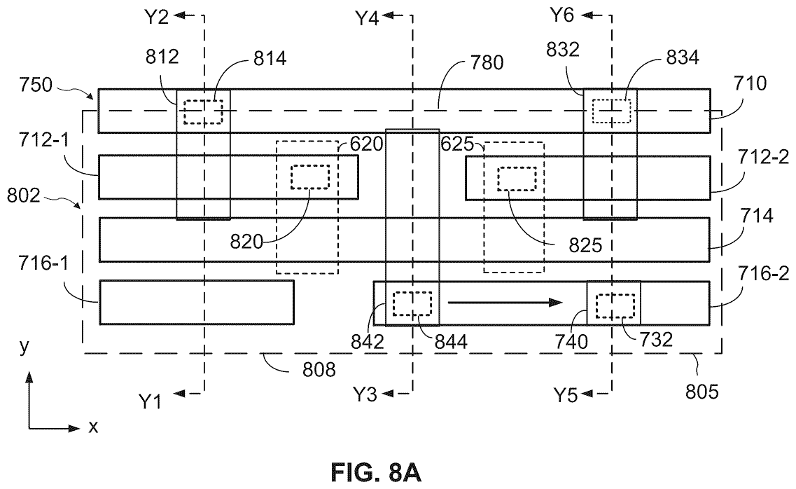

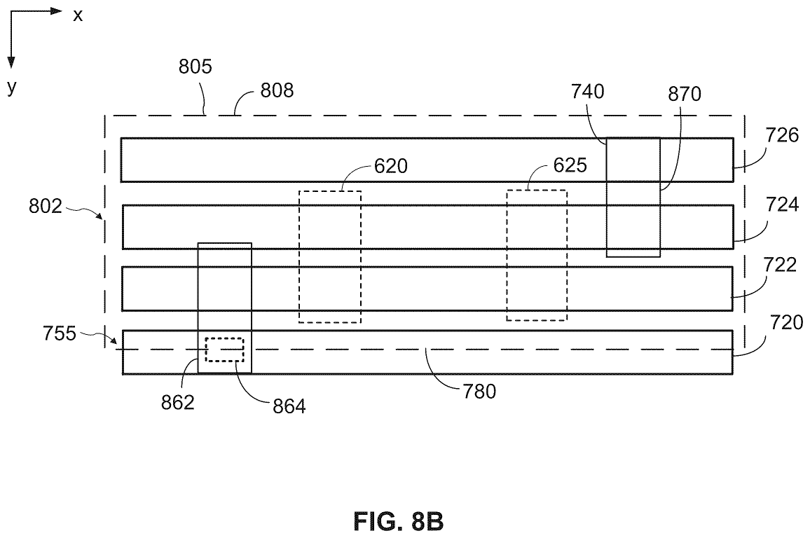

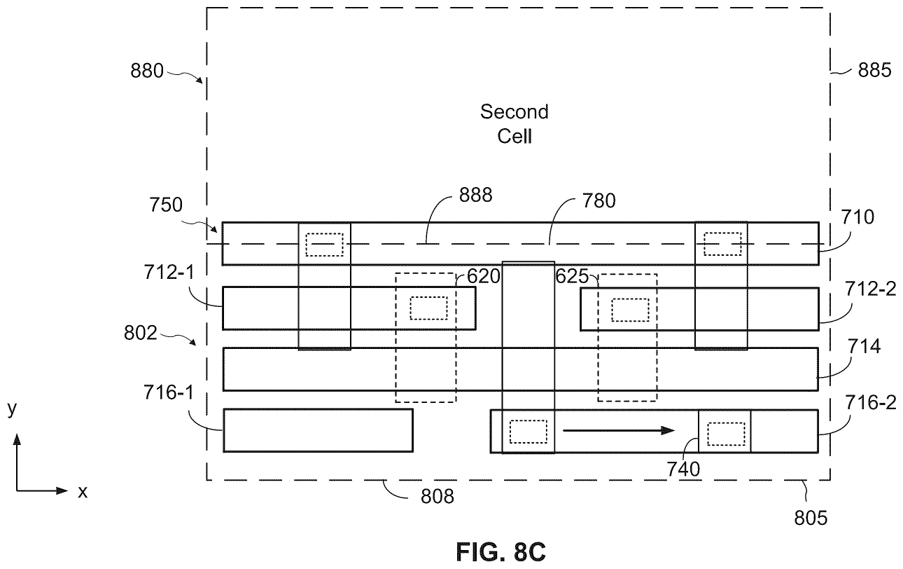

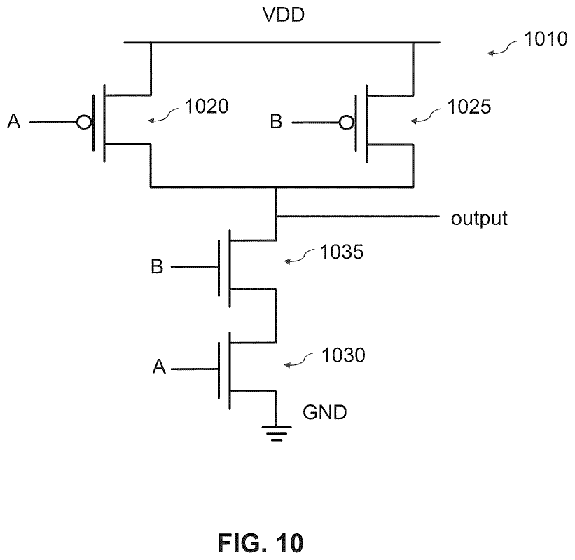

FIG. 8A shows a top view of the topside tracks 710, 712, 714, and 716 and FIG. 8B shows a bottom view of the backside tracks 720, 722, 724, and 726 for the example in which the CFET structure 610 implements the NAND gate. A circuit schematic of the NAND gate is provided in FIG. 10. The top view shown in FIG. 8A is a view of the topside tracks 710, 712, 714, and 716 looking down from the top in the direction 770 shown in FIG. 7, and the bottom view shown in FIG. 8B is a view of the backside tracks 720, 722, 724, and 726 looking up from the bottom in the direction 775 shown in FIG. 7. Note that the topside tracks 710, 712, 714, and 716 are transparent in FIG. 8A in order to show structures located below the topside tracks 710, 712, 714, and 716, and the backside tracks 720, 722, 724, and 726 are transparent in FIG. 8B in order to show structures located above the backside tracks 720, 722, 724, and 726. In FIGS. 8A and 8B, vias are shown in dotted line and gates are shown in dashed line.

Referring to FIG. 8A, in this example, a first topside contact 812 is disposed on a top surface of the first source/drain 632 (shown in FIGS. 6A and 6B). The first topside contact 812 extends in the y direction under the supply rail 750 (e.g., the topside track 710). A via 814 disposed between the first topside contact 812 and the supply rail 750 couples the first topside contact 812 to the supply rail 750. Thus, in this example, the first source/drain 632 is coupled to the supply rail 750 through the first topside contact 812 and the via 814.

In this example, a second topside contact 832 is disposed on a top surface of the third source/drain 636 (shown in FIGS. 6A and 6B). The second topside contact 832 extends in the y direction under the supply rail 750 (e.g., the topside track 710). A via 834 disposed between the second topside contact 832 and the supply rail 750 couples the second topside contact 832 to the supply rail 750. Thus, in this example, the third source/drain 636 is coupled to the supply rail 750 through the second topside contact 832 and the via 834.

In this example, the topside track 712 is cut into a first input signal path 712-1 and a second input signal path 712-2. A via 820 disposed between the first input signal path 712-1 and the first gate 620 (shown in dashed line) couples the first input signal path 712-1 to the first gate 620. A via 825 disposed between the second input signal path 712-2 and the second gate 625 (shown in dashed line) couples the second input signal path 712-2 to the second gate 625. In this example, the first input signal path 712-1 provides a first input of the NAND gate and the second input signal path 712-2 provides a second input of the NAND gate.

A third topside contact 842 is disposed on a top surface of the second source/drain 634 (shown in FIGS. 6A and 6B). The third topside contact 842 extends in the y direction under the topside track 716. In the example in FIG. 8A, the topside track 716 is cut into a first portion 716-1 and a second portion 716-2, in which the second portion 716-2 provides an output signal path for the NAND gate. In this example, a via 844 disposed between the third topside contact 842 and the second portion 716-2 of the topside track 716 (i.e., the output signal path in this example) couples the third topside contact 842 to the second portion 716-2 of the topside track 716. In this example, the vertical connector 740 is coupled to the second portion 716-2 of the topside track 716 to provide P-N coupling, as discussed further below. In the shown in FIG. 8A, the vertical connector 740 is coupled to the second portion 716-2 of the topside track 716 through the first vias 732 disposed between the second portion 716-2 of the topside track 716 and the vertical connector 740.

Referring to FIG. 8B, a first backside contact 862 is disposed on a bottom surface of the fourth source/drain 642 (shown in FIGS. 6A and 6B). The first backside contact 862 extends in the y direction above the ground rail 755 (e.g., the backside track 720). A via 864 disposed between the ground rail 755 and the first backside contact 862 couples the ground rail 755 to the first backside contact 862. Thus, in this example, the fourth source/drain 642 is coupled to the ground rail 755 through the first backside contact 862 and the via 864.

A second backside contact 870 is disposed on a bottom surface of the sixth source/drain 646 (shown in FIGS. 6A and 6B). The second backside contact 870 extends in the y direction and is coupled to the vertical connector 740. Thus, the second backside contact 870 is coupled to the output signal path (i.e., second portion 716-2 of the topside track 716 in this example) through the vertical connector 740 in this example.

In some implementations, the vertical connector 740 may also be coupled to the backside track 726 through the second via 734 (not shown in FIG. 8B). However, it is to be appreciated that the second via 734 may be omitted in other implementations. As discussed further below, the second via 734 allows a designer to control whether the vertical connector 740 is coupled to the backside track 726 by including or omitting the second via 734.

In certain aspects, the CFET structure 610 may be included in a standard cell 802. In this regard, FIGS. 8A and 8B shows an example of the cell boundary 805 of the cell 802 in dashed line. The cell boundary 805 includes the edge 780 discussed above and an edge 808 opposite the edge 780. In this example, the topside tracks 712, 714, and 716 and the backside tracks 726, 724, and 722 are located within the cell boundary 805 between the edges 780 and 808.

In the example shown in FIGS. 8A and 8B, the supply rail 750 and the ground rail 755 are located on the edge 780 of the cell boundary 805, in which the edge 780 extends in the x direction. Locating the supply rail 750 and the ground rail 755 on the edge 780 of the cell boundary 805 allows the supply rail 750 and the ground rail 755 to be shared with a neighboring cell located in an adjacent row for improved area efficiency.

In this regard, FIG. 8C shows a top view of an example in which the cell 802 shares the supply rail 750 and the ground rail 755 with a second cell 880. The second cell 880 is located in a row that is adjacent to the row in which the cell 802 is located. In this example, the edge 888 of the cell boundary 885 of the second cell 880 abuts the edge 780 of the cell boundary 805 of the cell 802, and the supply rail 750 and the ground rail 755 (not shown in FIG. 8C) are located on both edges 888 and 780. As a result, the supply rail 750 overlaps both cells 802 and 880, and the ground rail 755 overlaps both cells 802 and 880. This allows both cells 802 and 880 to access the supply rail 750 and the ground rail 755 for receiving power. Sharing the supply rail 750 and the ground rail 755 between the cells 802 and 880 improves area efficiency compared with providing the cells 802 and 880 with separate supply rails and separate ground rails.

The second cell 880 may include a CFET structure (e.g., second instance of the CFET structure 610). The chip 100 may also include topside tracks (e.g., second instance of the topside tracks 712, 714, and 716), backside tracks (e.g., second instance of the backside tracks 722, 724, and 726), and a vertical connector (e.g., second instance of the vertical connector 740) to provide signal routing for the second cell 880. The arrangement of the topside tracks for the second cell 880 may be flipped in the y direction with respect to the arrangement of the topside tracks 712, 714, 716 for the cell 802. Also, the arrangement of the backside tracks for the second cell 880 may be flipped in the y direction with respect to the arrangement of the backside tracks 724, 724, and 726 for the cell 802 (shown in FIG. 8B).

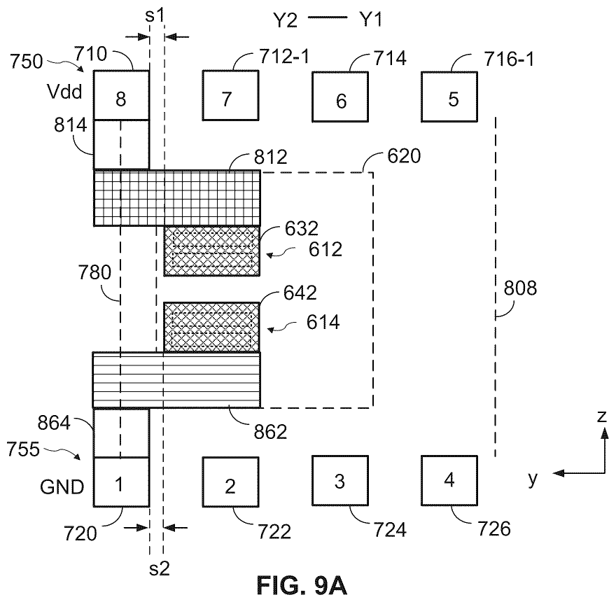

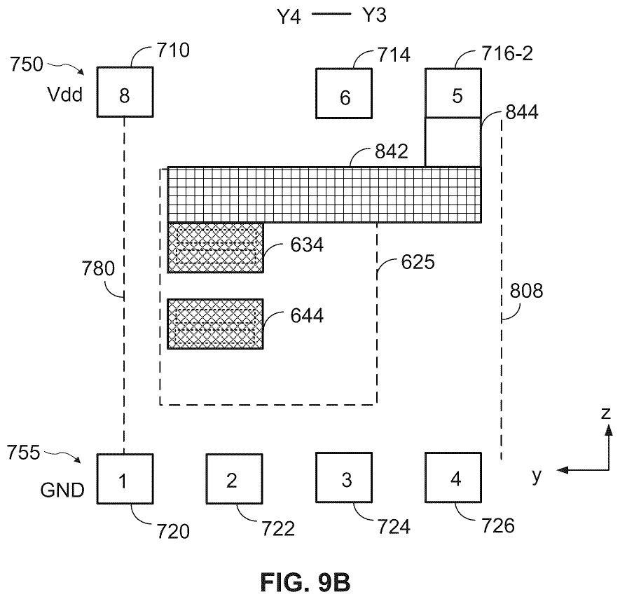

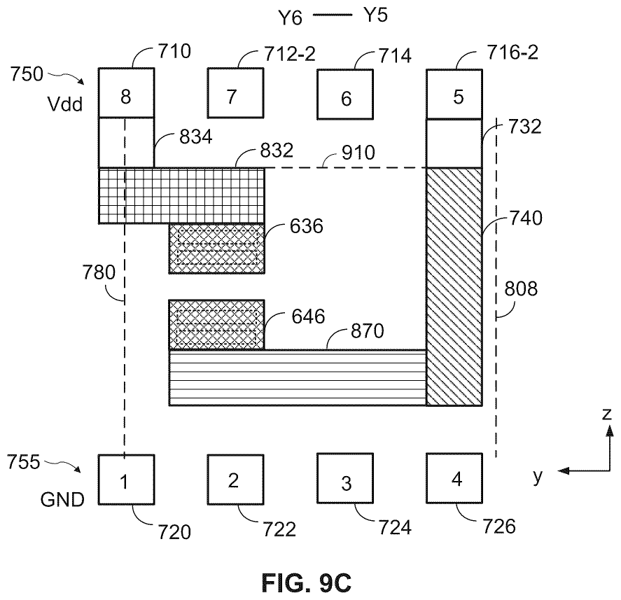

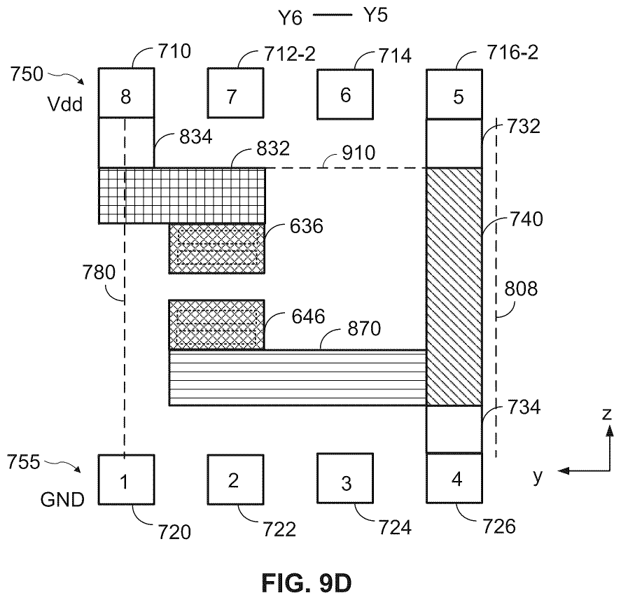

FIG. 9A shows a cross-sectional view taken along cross-section line Y2-Y1 in FIG. 8A. As shown in FIG. 9A, the first source/drain 632 is coupled to the supply rail 750 (e.g., topside track 710) through the first topside contact 812 and the via 814. The fourth source/drain 642 is coupled to the ground rail 755 (e.g., the backside track 720) through the first backside contact 862 and the via 864. Note that the cross-section line Y2-Y1 does not intersect the first gate 620. The first gate 620 is shown in dashed line in FIG. 9A to indicate the location of the first gate 620 in the y direction and the z direction.

As shown in FIG. 9A, the supply rail 750 and the ground rail 755 are in-line vertically at the edge 780 of the cell boundary 805. In other words, the supply rail 750 and the ground rail 755 are aligned in the y direction.

In this example, the supply rail 750 and the first diffusion region 612 are spaced apart in the y direction, and the ground rail 755 and the second diffusion region 614 are spaced apart in the y direction. In FIG. 9A, the space between the supply rail 750 and the first diffusion region 612 in the y direction is labeled s1, and the space between the ground rail 755 and the second diffusion region 614 in the y direction is labeled s2 where s2 may be equal to s1. In this example, spacing the diffusion regions 612 and 614 apart from the supply rail 750 and the ground rail 755 in the y direction allows the supply rail 750 and the ground rail 755 to be shared with diffusion regions in an adjacent cell (not shown) without the diffusion regions 612 and 614 interfering with the diffusion regions in the adjacent cell.

In the example shown in FIG. 9A, the first topside contact 812 extends in the y direction from the top surface of the first source/drain 632 to an area directly under the supply rail 750 to couple the first source/drain 632 to the supply rail 750 through the via 814. The first backside contact 862 extends from in the y direction from the bottom surface of the fourth source/drain 642 to an area directly above the ground rail 755 to couple the fourth source/drain 642 to the ground rail 755 through the via 864.

FIG. 9B shows a cross-sectional view taken along cross-section line Y4-Y3 in FIG. 8A. As shown in FIG. 9B, the second source/drain 634 is coupled to the output signal path (i.e., the second portion 716-2 of the topside track 716 in this example) through the third topside contact 842 and the via 844. The third topside contact 842 extends in the y direction from the top surface of the second source/drain 634 to an area directly below the second portion 716-2 of the topside track 716 to couple the second source/drain 634 to the second portion 716-2 of the topside track 716 through the via 844. Note that the cross-section line Y4-Y3 does not intersect the second gate 625. The second gate 625 is shown in dashed line in FIG. 9B to indicate the location of the second gate 625 in the y direction and the z direction.

FIG. 9C shows a cross-sectional view taken along cross-section line Y6-Y5 in FIG. 8A. As shown in FIG. 9C, the third source/drain 636 is coupled to the supply rail 750 (e.g., topside track 710) through the second topside contact 832 and the via 834. In this example, the second topside contact 832 extends in the y direction from the top surface of the third source/drain 636 to an area directly below the supply rail 750 to couple the third source/drain 636 to the supply rail 750 through the via 834.

Also, as shown in FIG. 9C, the sixth source/drain 646 is coupled to the vertical connector 740 through the second backside contact 870, in which the second backside contact 870 extends in the y direction from the bottom surface of the sixth source/drain 646 to the vertical connector 740. In this example, the vertical connector 740 is used to couple the sixth source/drain 646 to the output signal path (i.e., the second portion 716-2 of the topside track 716 in this example).

In the example shown in FIG. 9C, the second via 734 is omitted. FIG. 9D shows another example in which the vertical connector 740 is also coupled to the backside track 726 through the second via 734. Thus, the examples in FIGS. 9C and 9D illustrate that the second via 734 allows a designer to control whether the vertical connector 740 is coupled to the backside track 726 by including or omitting the second via 734. In these examples, the vertical connector 740 is coupled to the backside track 726 when the second via 734 is included (shown in FIG. 9D), and the vertical connector 740 is not coupled to the backside track 726 when the second via 734 is omitted (shown in FIG. 9C).

In the example shown in FIGS. 9C and 9D, the bottom of the vertical connector 740 is flush (i.e., planar) with the bottom of the second backside contact 870, and the second via 734 (shown in FIG. 9D) has the same height in the z direction as the via 864 (shown in FIG. 9A) used to couple the first backside contact 862 to the ground rail 755. This allows the vias 734 and 864 to be formed using the same process flow for process efficiency.

In the examples shown in FIGS. 9C and 9D, the first via 732 allows a designer to control whether the vertical connector 740 is coupled to the topside track 716 by including or omitting the first via 732. The vertical connector 740 is coupled to the topside track 716 when the first via 732 is included (shown in FIGS. 9C and 9D), and the vertical connector 740 is not coupled to the topside track 716 when the first via 732 is omitted (not shown).

In the examples shown in FIGS. 9C and 9D, the top of the vertical connector 740 is flush (i.e., planar) with the top of the second topside contact 832 (indicated by the line 910), and the first via 732 has the same height in the z direction as the via 834 (shown in FIGS. 9C and 9D) and the via 814 (shown in FIG. 9A). This allows the vias 732, 834, and 814 to be formed using the same process flow for process efficiency.

FIG. 10 shows a circuit schematic of the NAND gate 1010 implemented by the CFET structure 610 using the routing structure 705 in the example shown in FIGS. 8A, 8B, 9A, 9B, 9C, and 9D. However, it is to be appreciated that the CFET structure 610 is not limited to this example, and that the CFET structure 610 may implement other types of circuits using the routing structure 705.

In this example, the NAND gate 1010 includes a first PFET 1020, a second PFET 1025, a first NFET 1030, and a second NFET 1035. The first PFET 1020 and the second PFET 1025 are coupled in parallel between the supply rail (e.g., topside track 710) and the output of the NAND gate 1010 (e.g., the second portion 716-2 of the topside track 716), in which the sources of the first PFET 1020 and the second PFET 1025 are coupled to the supply rail, and the drains of the first PFET 1020 and the second PFET 1025 are coupled to the output. The gate (e.g., the first gate 620) of the first PFET 1020 is coupled to the first input (labeled A in FIG. 10) and the gate (e.g., the second gate 625) of the second PFET 1025 is coupled to the second input (e.g., labeled B in FIG. 10).

The first NFET 1030 and the second NFET 1035 are coupled in series between the output of the NAND gate 1010 and the ground rail (e.g., backside track 720), in which the source of the first NFET 1030 is coupled to the ground rail, the drain of the first NFET 1030 is coupled to the source of the second NFET 1035, and the drain of the second NFET 1035 is coupled to the output (e.g., through the vertical connector 740). The gate (e.g., the first gate 620) of the first NFET 330 is coupled to the first input (labeled A in FIG. 10) and the gate (e.g., the second gate 625) of the second NFET 1035 is coupled to the second input (labeled B in FIG. 10).

In this example, the first source/drain 632, the first gate 620, and the second source/drain 634 implement the source, the gate, and the drain, respectively, of the first PFET 1020. The third source/drain 364, the second gate 625, and the second source/drain 634 implement the source, the gate, and the drain, respectively, of the second PFET 1025. The fifth source/drain 644, the first gate 620, and the fourth source/drain 642 implement the drain, the gate, and the source of the first NFET 1030. The sixth source/drain 646, the second gate 625, and the fifth source/drain 644 implement the drain, the gate, and the source of the second NFET 1035.

In the example shown in FIGS. 8A and 8B, the vertical connector 740 is aligned with the second backside contact 870 and offset from the third topside contact 842 in the x direction. However, it is to be appreciated that the present disclosure is not limited to this example. For example, in some implementations, the vertical connector 740 may be offset from both the second backside contact 870 and the third topside contact 842 in the x direction.

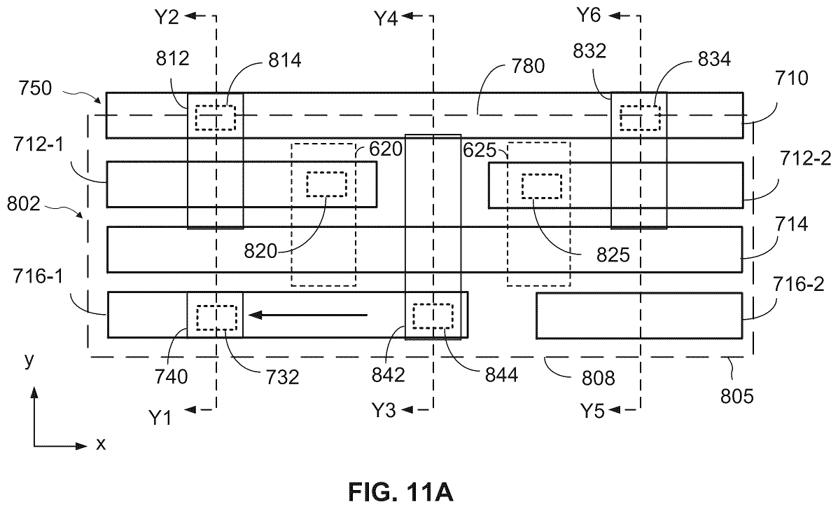

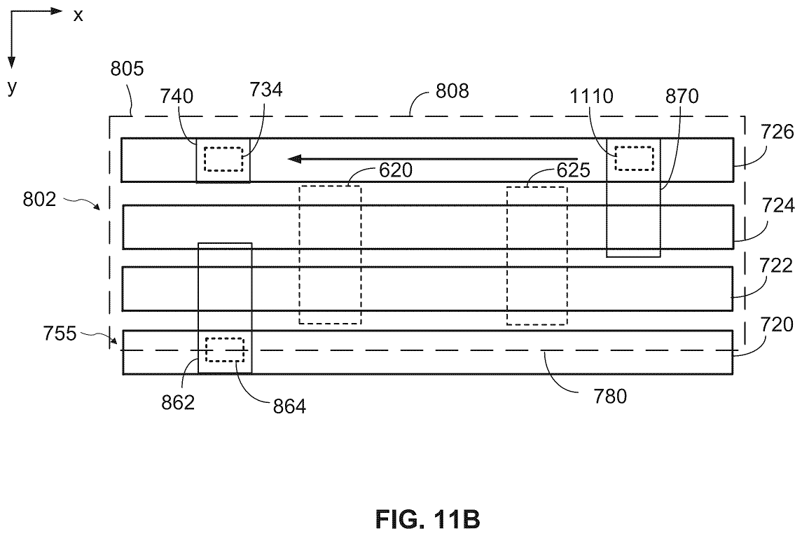

In this regard, FIG. 11A shows a top view of the topside tracks 710, 712, 714, and 716 and FIG. 11B shows a bottom view of the backside tracks 720, 722, 724, and 726 for the example where the vertical connector 740 is offset from both the second backside contact 870 and the third topside contact 842 in the x direction. In this example, the first portion 716-1 of the topside track 716 provides the output signal path.

Referring to FIG. 11A, the third topside contact 842 is coupled to the first portion 716-1 of the topside track 716 (i.e., output signal path in this example) through the via 844, which is disposed between the third topside contact 842 and the first portion 716-1 of the topside track 716. In this example, the vertical connector 740 is offset from the third topside contact 842 in the x direction. The vertical connector 740 is coupled to the first portion 716-1 of the topside track 716 through the first via 732, which is disposed between the first portion 716-1 of the topside track 716 and the vertical connector 740.

Referring to FIG. 11B, the second backside contact 870 extend in the y direction above the backside track 726. A via 1110 disposed between the backside track 726 and the second backside contact 870 couples the second backside contact 870 to the backside track 726. In this example, the vertical connector 740 is offset from the second backside contact 870 in the x direction, and the vertical connector 740 is coupled to the backside track 726 through the second via 734.

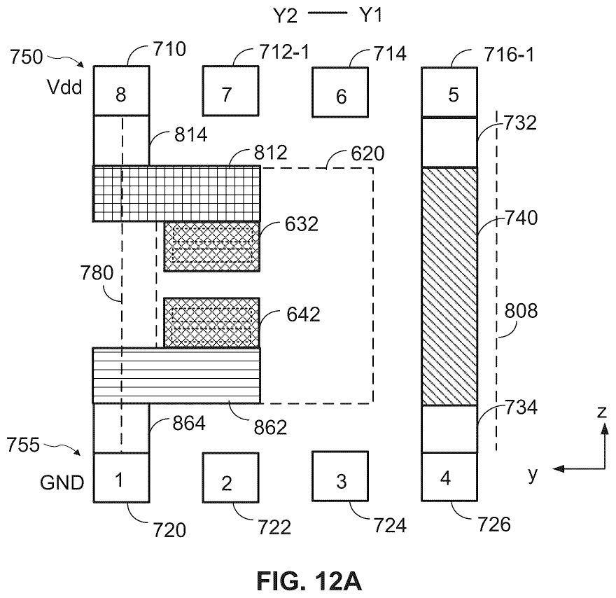

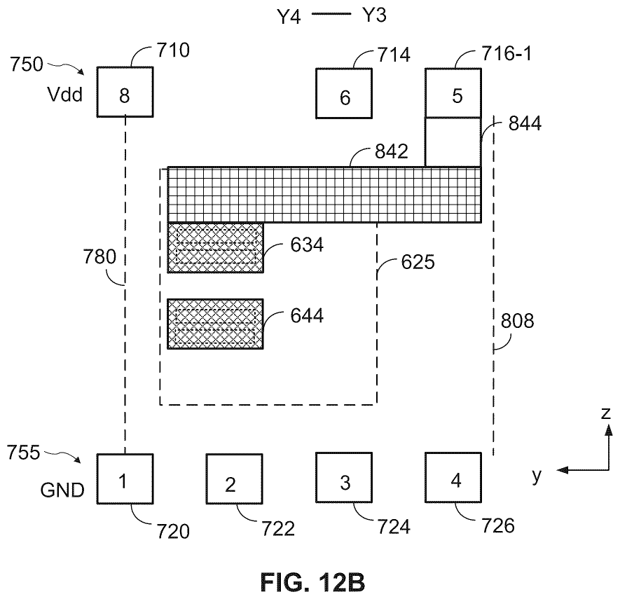

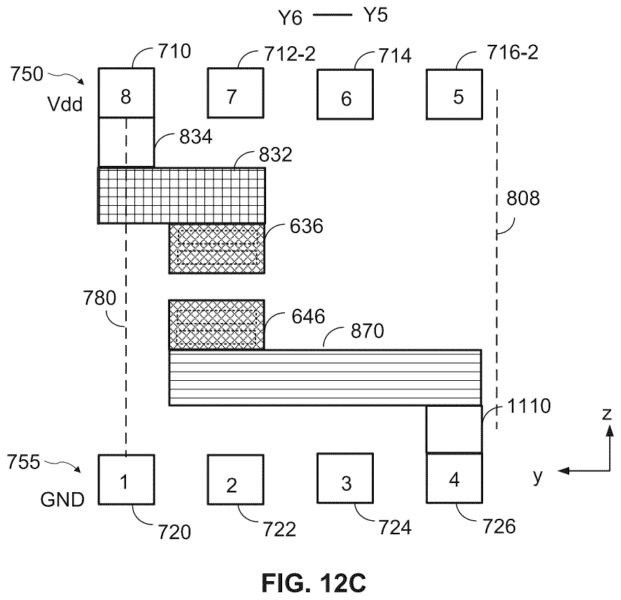

FIG. 12A shows a cross-sectional view taken along cross-section line Y2-Y1 in FIG. 11A. As shown in FIG. 12A, the first source/drain 632 is coupled to the supply rail 750 (e.g., topside track 710) through the first topside contact 812 and the via 814. The fourth source/drain 642 is coupled to the ground rail 755 (e.g., the backside track 720) through the first backside contact 862 and the via 864. The vertical connector 740 is coupled between the first portion 716-1 of the topside track 716 (i.e., output signal path in this example) through the first via 732 disposed between the top of the vertical connector 740 and the first portion 716-1 of the topside track 716. The vertical connector 740 is also coupled to the backside track 726 through the second via 734 disposed between the bottom of the vertical connector 740 and the backside track 726.

FIG. 12B shows a cross-sectional view taken along cross-section line Y4-Y3 in FIG. 11A. As shown in FIG. 12B, the second source/drain 634 is coupled to the output signal path (i.e., the first portion 716-1 of the topside track 716 in this example) through the third topside contact 842 and the via 844.

FIG. 12C shows a cross-sectional view taken along cross-section line Y6-Y5 in FIG. 11A. As shown in FIG. 12C, the third source/drain 636 is coupled to the supply rail 750 (e.g., topside track 710) through the second topside contact 832 and the via 834. The sixth source/drain 646 is coupled to the backside track 726 through the second backside contact 870 and the via 1110. In this example, the second backside contact 870 extends in the y direction from the bottom surface of the sixth source/drain 646 to an area directly above the backside track 726 to couple the sixth source/drain 646 to the backside track 726 through the via 1110.

In certain aspects, the chip 100 employs backside power distribution using the backside layers 155 shown in FIGS. 1D and 1E. In these aspects, the chip 100 may include one or more routing structures for routing the supply voltage Vdd from the backside power distribution network to the topside track 710. The power routing allows the topside track 710 to be used as the supply rail 750 for the CFET structure 610 in this example.

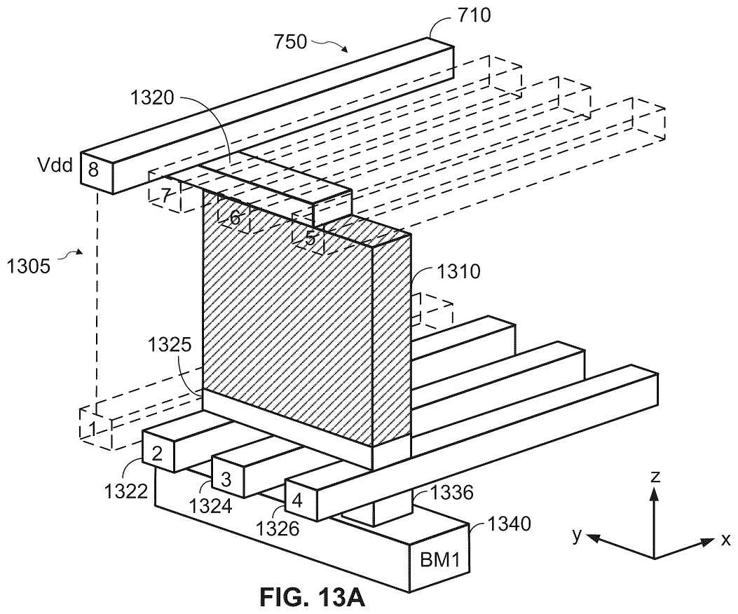

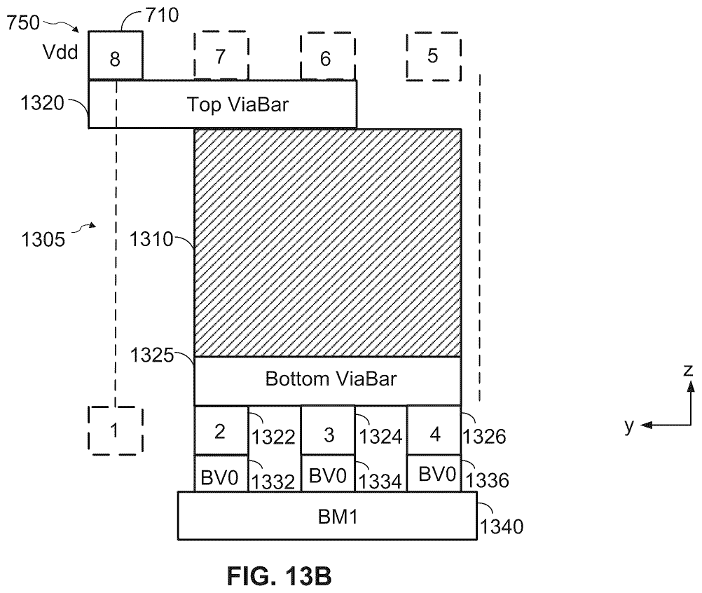

In this regard, FIG. 13A shows a perspective view and FIG. 13B shows a side view of an exemplary routing structure 1305 for routing the supply voltage Vdd from the backside power distribution network to the topside track 710 according to certain aspects. In this example, the routing structure 1305 includes a vertical connector 1310, a first via 1320, and a second via 1325. The vertical connector 1310 may be fabricated using the same process as the vertical connector 740 or a different process. In this example, the vertical connector 1310 is wider in the y direction than the vertical connector 740. Also, in this example, each of the vias 1320 and 1325 has a long rectangular shape to reduce feed through resistance and IR drop. In this regard, each of the vias 1320 and 1325 may also be referred to as “ViaBar” as shown in FIGS. 13A and 13B.

The first via 1320 extends in the y direction and is coupled between a top surface of the vertical connector 1310 and the topside track 710. The second via 1325 extends in the y direction and is coupled between a bottom surface of the vertical connector 1310 and the backside tracks 1322, 1324, and 1326. The backside tracks 1322, 1324, and 1326 may be aligned in the y direction with the backside tracks 722, 724, and 726, and may be formed in the same metal layer (e.g., metal layer BM0). FIGS. 13A and 13B shows the tracks labeled 1 and 5 to 7 in dashed line to indicate that these tracks may or may not be present since the routing structure 1305 does not use these tracks for routing the supply voltage Vdd in this example.

In the example shown in FIGS. 13A and 13B, the backside power distribution network includes a backside supply rail 1340 in backside metal lay BM1. The backside supply rail 1340 extends in the y direction under the backside tracks 1322, 1324, and 1326 and is coupled to the backside tracks 1322, 1324, and 1326 through vias 1332, 1334, and 1336 (e.g., BVO in FIGS. 1D and 1E), respectively. The backside supply rail 1340 provides the backside tracks 1322, 1324, and 1326 with the supply voltage Vdd from the backside supply distribution network.

In this example, the routing structure 1305 couples the supply voltage Vdd from the backside tracks 1322, 1324, and 1326 to the topside track 710. The topside track 710 may extend in the x direction to a cell including the CFET structure 610 to provide the CFET structure 610 with the supply voltage Vdd from the topside track 710.

It is to be appreciated that the chip 100 may include multiple instances of the routing structure 1305 arranged in parallel between the topside track 710 and the backside tracks 1322, 1324, and 1326. For example, one or more instances of the routing structure 1305 may be placed in a filler cell to route the supply voltage Vdd from the backside power distribution network to the topside track 710. In this example, the topside track 710 may extend in the x direction across multiple cells (e.g., the cell including the CFET structure 610) to provide the multiple cells with the supply voltage Vdd from the topside track 710.

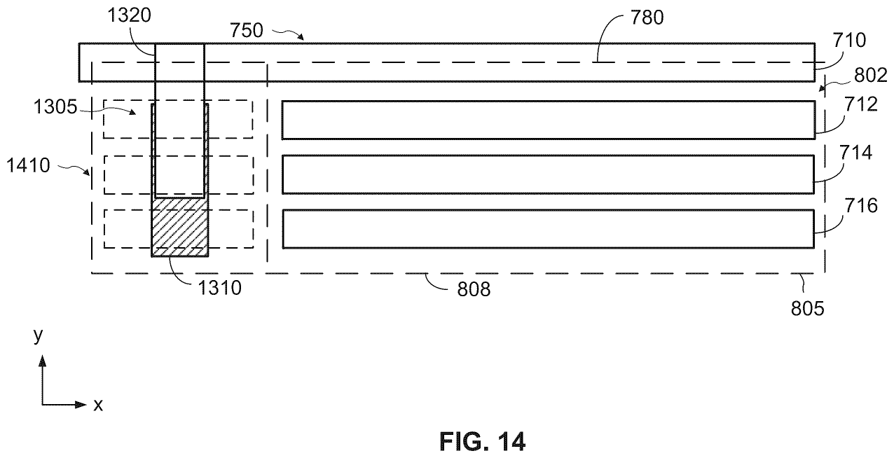

In this regard, FIG. 14 shows a top view of an example of a cell 1410 including the routing structure 1305. In this example, the cell 1410 and the cell 802 including the CFET structure 610 are located in the same row. However, it is to be appreciated that the present disclosure is not limited to this example. In other implementations, the cell 802 may be located in an adjacent row that shares the supply rail 750 with the row in which the cell 1410 is located.

In this example, the routing structure 1305 routes the supply voltage Vdd from the backside power distribution network to the supply rail 750 (e.g., topside track 710 in this example). The supply rail 750 extends in the x direction from the cell 1410 to the cell 802 to provide the supply voltage Vdd to the cell 802. In this example, the cell 802 receives the supply voltage Vdd from the supply rail 750. For example, the first diffusion region 612 (shown in FIGS. 9A and 9C and FIGS. 12A and 12C) in the cell 802 may be coupled to the supply rail 750 through contacts and vias (e.g., the contacts 812 and 832 and the vias 814 and 834). However, it is to be appreciated that the present disclosure is not limited to this example.

Implementation examples are described in the following numbered clauses:

1. A chip, comprising:
a first diffusion region extending in a first direction;
a second diffusion region extending in the first direction, wherein the first diffusion region and the second diffusion region are stacked in a second direction perpendicular to the first direction;
a first rail extending in the first direction, wherein the first rail is above the first diffusion region in the second direction, and the first diffusion region and the first rail are spaced apart in a third direction perpendicular to the first direction and the second direction;
a second rail extending in the first direction, wherein the second rail is below the second diffusion region in the second direction, and the second diffusion region and the second rail are spaced apart in the third direction;
a first topside contact coupled between a first top surface of the first diffusion region and the first rail; and
a first backside contact coupled between a first bottom surface of the second diffusion region and the second rail.

2. The chip of clause 1, wherein the first rail is a supply rail and the second rail is a ground rail.

3. The chip of clause 1 or 2, wherein the first diffusion region is a p-type diffusion region and the second diffusion region is an n-type diffusion region.

4. The chip of any one of clauses 1 to 3, wherein the first rail and the second rail are aligned in the third direction.

5. The chip of any one of clauses 1 to 4, wherein the first diffusion region comprises a first source/drain coupled to the first topside contact, and the second diffusion region comprises a second source/drain coupled to the first backside contact.

6. The chip of clause 5, wherein the first source/drain and the second source/drain are stacked in the second direction.

7. The chip of clause 5 or 6, further comprising a gate, wherein the first diffusion region comprises one or more first channels passing through the gate and coupled to the first source/drain, and the second diffusion region comprises one or more second channels passing through the gate and coupled to the second source/drain.

8. The chip of any one of clauses 1 to 7, further comprising:
a first track extending in the first direction, wherein the first track is above the first diffusion region in the second direction;
a second track extending in the first direction, wherein the second track is below the second diffusion region in the second direction;
a second topside contact coupled between a second top surface of the first diffusion region and the first track;
a second backside contact coupled between a second bottom surface of the second diffusion region and the second track; and
a vertical connector coupled between the first track and the second track.

9. The chip of clause 8, wherein the first track and the second track are aligned in the third direction.

10. The chip of clause 8 or 9, wherein the vertical connector extends in the second direction.

11. The chip of any one of clauses 8 to 10, wherein the first rail and the first track are aligned in the second direction, and the second rail and the second track are aligned in the second direction.

12. The chip of any one of clauses 8 to 11, wherein the vertical connector is offset from at least one of the second topside contact and the second backside contact in the first direction.

13. The chip of any one of clauses 8 to 12, wherein the vertical connector is offset from both the second topside contact and the second backside contact in the first direction.

14. A chip, comprising:
a first diffusion region extending in a first direction;
a second diffusion region extending in the first direction, wherein the first diffusion region and the second diffusion region are stacked in a second direction perpendicular to the first direction;
a first track extending in the first direction, wherein the first track is above the first diffusion region in the second direction;
a second track extending in the first direction, wherein the second track is below the second diffusion region in the second direction;
a first topside contact coupled between a first top surface of the first diffusion region and the first track;
a first backside contact coupled between a first bottom surface of the second diffusion region and the second track;
a vertical connector extending in the second direction between the first track and the second track;
a first via disposed between the vertical connector and the first track; and
a second via disposed between the vertical connector and the second track.

15. The chip of clause 14, further comprising:
a first rail extending in the first direction, wherein the first rail is above the first diffusion region in the second direction;
a second topside contact disposed on a second top surface of the first diffusion region, wherein the second topside contact extends in a third direction perpendicular to the first direction and the second direction; and
a third via disposed between the second topside contact and the first rail.

16. The chip of clause 15, wherein a height of the first via in the second direction is approximately equal to a height of the third via in the second direction.

17. The chip of clause 15 or 16, wherein a top surface of the vertical connector is flush with a top surface of the second topside contact in the second direction.

18. The chip of any one of clauses 15 to 17, wherein the first diffusion region comprises a first source/drain coupled to the first topside contact, and the second diffusion region comprises a second source/drain coupled to the first backside contact.

19. The chip of clause 18, wherein the first source/drain and the second source/drain are offset in the first direction.

20. The chip of any one of clauses 15 to 19, further comprising:
a second rail extending in the first direction, wherein the second rail is below the second diffusion region in the second direction;
a second backside contact disposed on a second backside surface of the second diffusion region, wherein the second backside contact extends in the third direction; and
a fourth via disposed between the second backside contact and the second rail.

21. The chip of clause 20, wherein a height of the second via in the second direction is approximately equal to a height of the fourth via in the second direction.

22. The chip of clause 20 or 21, wherein a bottom surface of the vertical connector is flush with a bottom surface of the second backside contact in the second direction.

23. The chip of any one of clauses 20 to 22, wherein the first rail is a supply rail and the second rail is a ground rail.

24. The chip of any one of clauses 20 to 23, wherein the first rail and the first track are aligned in the second direction, and the second rail and the second track are aligned in the second direction.

25. The chip of any one of clauses 14 to 24, wherein the vertical connector is offset from at least one of the first topside contact and the first backside contact in the first direction.

26. The chip of any one of clauses 14 to 25, wherein the vertical connector is offset from both the first topside contact and the first backside contact in the first direction.

27. A chip, comprising:
a first diffusion region extending in a first direction;
a second diffusion region extending in the first direction, wherein the first diffusion region and the second diffusion region are stacked in a second direction perpendicular to the first direction;
a track extending in the first direction, wherein the track is above the first diffusion region in the second direction;
a first topside contact coupled between a first top surface of the first diffusion region and the track;
a vertical connector extending in the second direction;
a first via disposed between the vertical connector and the track; and
a backside contact coupled between a bottom surface of the second diffusion region and the vertical connector.

28. The chip of clause 27, further comprising:
a rail extending in the first direction, wherein the rail is above the first diffusion region in the second direction;
a second topside contact disposed on a second top surface of the first diffusion region, wherein the second topside contact extends in a third direction perpendicular to the first direction and the second direction; and
a second via disposed between the second topside contact and the rail.

29. The chip of clause 28, wherein a height of the first via in the second direction is approximately equal to a height of the second via in the second direction.

30. The chip of clause 28 or 29, wherein a top surface of the vertical connector is flush with a top surface of the second topside contact in the second direction.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first diffusion region extending in a first direction;
a second diffusion region extending in the first direction, wherein the first diffusion region and the second diffusion region are stacked in a second direction perpendicular to the first direction;
a first rail extending in the first direction, wherein the first rail is above the first diffusion region in the second direction, and the first diffusion region and the first rail are spaced apart in a third direction perpendicular to the first direction and the second direction;
a second rail extending in the first direction, wherein the second rail is below the second diffusion region in the second direction, and the second diffusion region and the second rail are spaced apart in the third direction;
a first topside contact coupled between a first top surface of the first diffusion region and the first rail; and
a first backside contact coupled between a first bottom surface of the second diffusion region and the second rail.

2. The chip of claim 1, wherein the first rail is a supply rail and the second rail is a ground rail.

3. The chip of claim 1, wherein the first diffusion region is a p-type diffusion region and the second diffusion region is an n-type diffusion region.

4. The chip of claim 1, wherein the first diffusion region comprises a first source/drain coupled to the first topside contact, and the second diffusion region comprises a second source/drain coupled to the first backside contact.

5. The chip of claim 4, further comprising a gate, wherein the first diffusion region comprises one or more first channels passing through the gate and coupled to the first source/drain, and the second diffusion region comprises one or more second channels passing through the gate and coupled to the second source/drain.

6. The chip of claim 1, further comprising:
a first track extending in the first direction, wherein the first track is above the first diffusion region in the second direction;
a second track extending in the first direction, wherein the second track is below the second diffusion region in the second direction;
a second topside contact coupled between a second top surface of the first diffusion region and the first track;
a second backside contact coupled between a second bottom surface of the second diffusion region and the second track; and
a vertical connector coupled between the first track and the second track.

7. The chip of claim 6, wherein the first rail and the first track are aligned in the second direction, and the second rail and the second track are aligned in the second direction.

8. The chip of claim 6, wherein the vertical connector is offset from at least one of the second topside contact and the second backside contact in the first direction.

9. A chip, comprising:
a first diffusion region extending in a first direction;
a second diffusion region extending in the first direction, wherein the first diffusion region and the second diffusion region are stacked in a second direction perpendicular to the first direction;
a first track extending in the first direction, wherein the first track is above the first diffusion region in the second direction;
a second track extending in the first direction, wherein the second track is below the second diffusion region in the second direction;
a first topside contact coupled between a first top surface of the first diffusion region and the first track;
a first backside contact coupled between a first bottom surface of the second diffusion region and the second track;
a vertical connector extending in the second direction between the first track and the second track;
a first via disposed between the vertical connector and the first track; and
a second via disposed between the vertical connector and the second track.

10. The chip of claim 9, further comprising:
a first rail extending in the first direction, wherein the first rail is above the first diffusion region in the second direction;
a second topside contact disposed on a second top surface of the first diffusion region, wherein the second topside contact extends in a third direction perpendicular to the first direction and the second direction; and
a third via disposed between the second topside contact and the first rail.

11. The chip of claim 10, wherein a height of the first via in the second direction is approximately equal to a height of the third via in the second direction.

12. The chip of claim 10, wherein a top surface of the vertical connector is flush with a top surface of the second topside contact in the second direction.

13. The chip of claim 10, further comprising:
a second rail extending in the first direction, wherein the second rail is below the second diffusion region in the second direction;
a second backside contact disposed on a second backside surface of the second diffusion region, wherein the second backside contact extends in the third direction; and
a fourth via disposed between the second backside contact and the second rail.

14. The chip of claim 13, wherein a height of the second via in the second direction is approximately equal to a height of the fourth via in the second direction.

15. The chip of claim 13, wherein a bottom surface of the vertical connector is flush with a bottom surface of the second backside contact in the second direction.

16. The chip of claim 13, wherein the first rail and the first track are aligned in the second direction, and the second rail and the second track are aligned in the second direction.

17. The chip of claim 9, wherein the vertical connector is offset from at least one of the first topside contact and the first backside contact in the first direction.

18. A chip, comprising:
a first diffusion region extending in a first direction;
a second diffusion region extending in the first direction, wherein the first diffusion region and the second diffusion region are stacked in a second direction perpendicular to the first direction;
a track extending in the first direction, wherein the track is above the first diffusion region in the second direction;
a first topside contact coupled between a first top surface of the first diffusion region and the track;
a vertical connector extending in the second direction;
a first via disposed between the vertical connector and the track; and
a backside contact coupled between a bottom surface of the second diffusion region and the vertical connector.

19. The chip of claim 18, further comprising:
a rail extending in the first direction, wherein the rail is above the first diffusion region in the second direction;
a second topside contact disposed on a second top surface of the first diffusion region, wherein the second topside contact extends in a third direction perpendicular to the first direction and the second direction; and
a second via disposed between the second topside contact and the rail.

20. The chip of claim 19, wherein a height of the first via in the second direction is approximately equal to a height of the second via in the second direction.
